(19) United States
(12) Patent Application Publication
(10) Pub. No.: US 2016/0174365 A1
(43) Pub. Date: Jun. 16, 2016

(54) WIRING BOARD WITH DUAL WIRING STRUCTURES INTEGRATED TOGETHER AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 14/746,792

(22) Filed: Jun. 22, 2015

Related U.S. Application Data
(60) Provisional application No. 62/092,196, filed on Dec. 15, 2014.
(60) Provisional application No. 62/121,450, filed on Feb. 26, 2015.

(51) Int. Cl. H05K 1/02; H05K 3/46; H05K 3/10; H05K 1/11

(52) U.S. Cl. CPC H05K 1/0271; H05K 1/0298; H05K 1/115; H05K 3/4682; H05K 3/10

(57) ABSTRACT

A wiring board with integrated dual wiring structures is characterized in that first and second wiring structures are positioned within and beyond a through opening of a stiffener, respectively. The mechanical robustness of the stiffener can prevent the wiring board from warping. The first wiring structure, positioned within the through opening of the stiffener, can provide primary fan-out routing, whereas the second wiring structure not only provides further fan-out wiring structure for the first wiring structure, but also mechanically binds the first wiring structure with the stiffener.

### CROSS REFERENCE TO RELATED APPLICATIONS

This application claims the benefit of filing date of U.S. Provisional Application Ser. No. 62/092,196 filed Dec. 15, 2014 and the benefit of the filing date of U.S. Provisional Application Ser. No. 62/121,450 filed Feb. 26, 2015. The entirety of each said Provisional Applications is incorporated herein by reference.

### FIELD OF THE INVENTION

The present invention relates to a wiring board, more particularly, to a wiring board having integrated dual wiring structures within and beyond a through opening of a stiffener, respectively, and a method of making the same.

### DESCRIPTION OF RELATED ART

Market trends of electronic devices such as multimedia devices demand for faster and slimmer designs. One of the approaches is to interconnect semiconductor chip through a coreless substrate so that the assembled device can be thinner and signal integrity can be improved. U.S. Pat. Nos. 7,851,269, 7,902,660, 7,981,728, and 8,227,703 disclose various coreless substrates for such kind of purpose. However, although the inductance of these wiring boards can be reduced, other features such as design flexibility are not addressed as they do not have adequate fan-out routing capability to meet stringent requirements for ultra-fine flip chip assembly.

For the reasons stated above, and for other reasons stated below, an urgent need exists to develop a new wiring board that can address routing requirement and ensure low warping during assembly and operation.

### SUMMARY OF THE INVENTION

A primary objective of the present invention is to provide a wiring board having first and second wiring structures integrated together so as to enable high routing flexibility and achieve superior signal integrity. For instance, the first wiring structure can be configured as primary fan-out circuitry with very high routing density and the second wiring structure can be configured as further fan-out circuitry with much coarse line/space for next-level board assembling. The two wiring structures integrated together can offer the shortest possible interconnection length for the wiring board, thereby reducing the inductance and improving the electrical performance of the assembly.

Another objective of the present invention is to provide a wiring board in which a stiffener is used to provide mechanical support for the first wiring structure and also serve as a platform for the second wiring structure formed thereon so as to suppress warping and bending of the wiring board, thereby improving the mechanical reliability of the wiring board.

Yet another objective of the present invention is to provide a wiring board having the first wiring structure positioned within a through opening of the stiffener and the second wiring structure positioned beyond the through opening of the stiffener, thereby improving the production yield of the wiring board.

In accordance with the foregoing and other objectives, the present invention proposes a wiring board that includes a stiffener, a first wiring structure and a second wiring structure. In a preferred embodiment, the stiffener, having a through opening, provides a high modulus anti-warping platform for the integrated dual wiring structures; the first wiring structure, positioned within the through opening of the stiffener, provides primary fan-out routing for a semiconductor device to be assembled thereon so that the pad size and pitch of the semiconductor device can be enlarged before proceeding the subsequent formation of the second wiring structure; and the second wiring structure, laterally extending on the stiffener and electrically connected to the first wiring structure, mechanically binds the first wiring structure with the stiffener and provides secondary fan-out routing for the semiconductor device and has pad pith and size that match the next level assembly. Optionally, the wiring board may further include an anti-warping controller on the second wiring structure.

In another aspect, the present invention provides a method of making a wiring board with dual wiring structures integrated together, comprising steps of: forming a first wiring structure on a detachable sacrificial carrier; providing a stiffener that has a through opening extending through the stiffener; inserting the first wiring structure and the sacrificial carrier into the through opening of the stiffener; forming a second wiring structure that is electrically coupled to the first wiring structure and includes at least one conductive trace laterally extending over a surface of the stiffener; optionally attaching an anti-warping controller on the second wiring structure; and removing the sacrificial carrier to expose the first wiring structure.

Unless specifically indicated or using the term “then” between steps, or steps necessarily occurring in a certain order, the sequence of the above-mentioned steps is not limited to that set forth above and may be changed or reordered according to desired design.

In yet another aspect, the present invention provides a wiring board, including a stiffener, a first wiring structure, a second wiring structure, and optionally an anti-warping controller, wherein (i) the stiffener has a through opening that extends through the stiffener; (ii) the first wiring structure has a multi-layered routing circuitry and is positioned within the through opening of the stiffener; (iii) the second wiring structure is electrically coupled to the contact pads of the first wiring structure and includes at least one conductive trace laterally extending over a surface of the stiffener; and (iv) the optional anti-warping controller is attached on the second wiring structure and preferably is centrally aligned with the through opening of the stiffener.

The method of making a wiring board according to the present invention has numerous advantages. For instance, inserting the sacrificial carrier and the first wiring structure into the through opening of the stiffener before the formation of the second wiring structure is particularly advantageous as the sacrificial carrier together with the stiffener provides a stable platform for forming the second wiring structure and micro-via connection failure in the subsequent formation of the second wiring structure can be avoided. Additionally, the two-stage formation of the interconnect substrate can avoid serious warping problem when multiple layers of wiring circuitries are needed.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, showing a structure with routing traces formed on a sacrificial carrier in accordance with the first embodiment of the present invention;

FIG. 3 is a cross-sectional view showing the structure of FIG. 1 is provided with an insulating layer and via openings in accordance with the first embodiment of the present invention;

FIG. 4 is a cross-sectional view showing a state in which the structure of FIG. 3 is provided with conductive traces in accordance with the first embodiment of the present invention;

FIG. 5 is a cross-sectional view showing the structure of FIG. 4 is provided with an insulating layer and via openings in accordance with the first embodiment of the present invention;

FIGS. 6 and 7 are cross-sectional and top perspective views, respectively, showing the structure of FIG. 5 is provided with conductive traces in accordance with the first embodiment of the present invention;

FIGS. 8 and 9 are cross-sectional and top perspective views, respectively, of a diced state of the panel-scale structure of FIGS. 6 and 7 in accordance with the first embodiment of the present invention;

FIG. 10 is a cross-sectional view of a subcomponent corresponding to a diced unit in FIGS. 8 and 9 in accordance with the first embodiment of the present invention;

FIG. 11 is a cross-sectional view of a stiffener on a carrier film in accordance with the first embodiment of the present invention;

FIGS. 12 and 13 are cross-sectional and top perspective views, respectively, showing the subcomponent of FIG. 10 is attached to the carrier film of FIG. 11 in accordance with the first embodiment of the present invention;

FIG. 14 is a cross-sectional view showing laminated layers are disposed on the structure of FIG. 12 in accordance with the first embodiment of the present invention;

FIG. 15 is a cross-sectional view showing the structure of FIG. 14 is provided with via openings in accordance with the first embodiment of the present invention;

FIG. 16 is a cross-sectional view showing the structure of FIG. 15 is provided with conductive traces in accordance with the first embodiment of the present invention;

FIG. 17 is a cross-sectional view showing the carrier film and the sacrificial carrier are removed from the structure of FIG. 16 to finish the fabrication of a wiring board in accordance with the first embodiment of the present invention;

FIG. 18 is a cross-sectional view of a semiconductor assembly with a semiconductor device mounted on the wiring board of FIG. 17 in accordance with the first embodiment of the present invention;

FIG. 19 is a cross-sectional view of a package-on-package assembly with another semiconductor device further electrically coupled to the semiconductor assembly of FIG. 18 in accordance with the first embodiment of the present invention;

FIG. 20 is a cross-sectional view showing a structure with a subcomponent and a stiffener on an insulating layer/a metal layer in accordance with the second embodiment of the present invention;

FIG. 21 is a cross-sectional view showing the structure of FIG. 20 is subjected to a lamination process in accordance with the second embodiment of the present invention;

FIG. 22 is a cross-sectional view showing the structure of FIG. 21 is provided with via openings in accordance with the second embodiment of the present invention;

FIGS. 23 and 24 are cross-sectional and top perspective views, respectively, showing the structure of FIG. 22 is provided with conductive traces and a registration mark in accordance with the second embodiment of the present invention;

FIGS. 25 and 26 are cross-sectional and top perspective views, respectively, showing the structure of FIGS. 23 and 24 is provided with an anti-warping controller in accordance with the second embodiment of the present invention;

FIG. 27 is a cross-sectional view showing the support sheet of the sacrificial carrier is removed from the structure of FIG. 25 in accordance with the second embodiment of the present invention;

FIG. 28 is a cross-sectional view showing the barrier layer of the sacrificial carrier is removed from the structure of FIG. 27 to finish the fabrication of another wiring board in accordance with the second embodiment of the present invention;

FIG. 29 is a cross-sectional view of another semiconductor assembly with a semiconductor device mounted on the wiring board of FIG. 28 in accordance with the second embodiment of the present invention;

FIG. 30 is a cross-sectional view of yet another wiring board in accordance with the third embodiment of the present invention; and

FIG. 31 is a cross-sectional view of yet another semiconductor assembly with a semiconductor device mounted on the wiring board of FIG. 30 in accordance with the third embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the disclosure of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

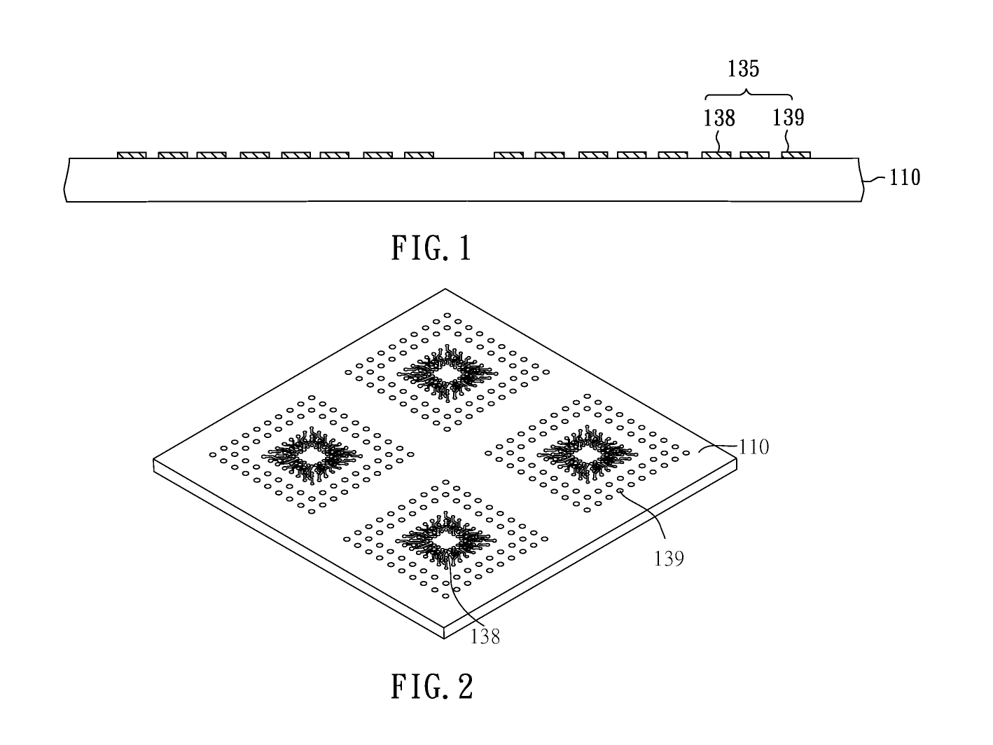

FIGS. 1-17 are schematic views showing a method of making a wiring board that includes a stiffener, a first wiring structure and a second wiring structure in accordance with an embodiment of the present invention.

FIGS. 1 and 2 are cross-sectional and top perspective views, respectively, of the structure with routing traces 135 formed on a sacrificial carrier 110 by metal deposition and metal patterning process. In this illustration, the sacrificial carrier 110 is a single-layer structure, and the routing traces 135 include bond pads 138 and stacking pads 139. The sacrificial carrier 110 typically is made of copper, aluminum, iron, nickel, tin, stainless steel, silicon, or other metals or alloys, but any other conductive or non-conductive material also may be used. The thickness of the sacrificial carrier 110 preferably ranges from 0.1 to 2.0 mm. In this embodiment, the sacrificial carrier 110 is made of an iron-based material and has a thickness of 1.0 mm. The routing traces 135 typically are made of copper and can be pattern deposited by numerous techniques, such as electroplating, electroless plating, evaporating, sputtering or their combinations, or be thin-film deposited followed by a metal patterning process. For a conductive sacrificial carrier 110, the routing traces 135 are deposited typically by plating of metal. The metal patterning techniques include wet etching, electro-chemical etching, laser-assist etching, and their combinations with an etch mask (not shown) thereon that defines the routing traces 135.

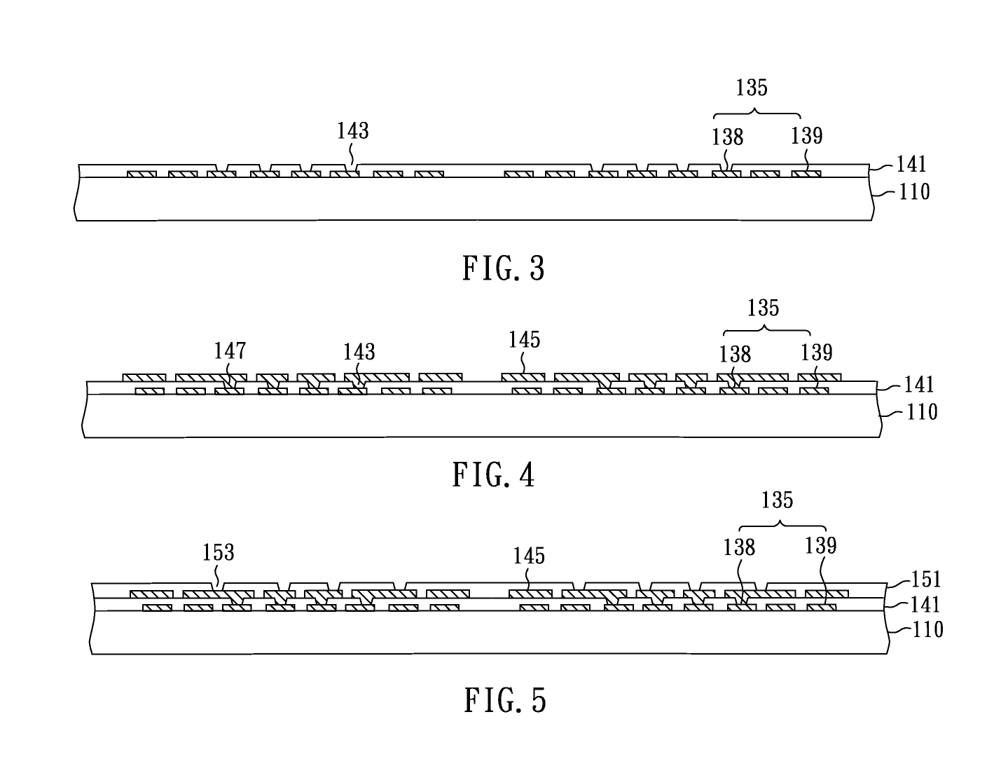

FIG. 3 is a cross-sectional view of the structure with a first insulating layer 141 on the sacrificial carrier 110 as well as the routing traces 135 and first via openings 143 in the first insulating layer 141. The first insulating layer 141 is deposited typically by lamination or coating, and contacts and covers and extends laterally on the sacrificial carrier 110 and the routing traces 135 from above. The first insulating layer 141 typically has a thickness of 50 microns, and can be made of epoxy resin, glass-epoxy, polyimide, or the like. After the deposition of the first insulating layer 141, the first via openings 143 are formed by numerous techniques including laser drilling, plasma etching and photolithography, and typically have a diameter of 50 microns. Laser drilling can be enhanced by a pulsed laser. Alternatively, a scanning laser beam with a metal mask can be used. The first via openings 143 extend through the first insulating layer 141 and are aligned with selected portions of the routing traces 135.

Referring now to FIG. 4, first conductive traces 145 are formed on the first insulating layer 141 by metal deposition and metal patterning process. The first conductive traces 145 extend from the routing traces 135 in the upward direction, fill up the first via openings 143 to form first conductive vias 147 in direct contact with the routing traces 135, and extend laterally on the first insulating layer 141. As a result, the first conductive traces 145 can provide horizontal signal routing in both the X and Y directions and vertical routing through the first via openings 143 and serve as electrical connections for the routing traces 135.

The conductive traces 145 can be deposited as a single layer or multiple layers by any of numerous techniques, such as electroplating, electroless plating, evaporating, sputtering, or their combinations. For instance, they can be deposited by first dipping the structure in an activator solution to render the first insulating layer 141 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the first conductive traces 145 by any of numerous techniques including wet etching, electro-chemical etching, laser-assist etching, and their combinations, with an etch mask (not shown) thereon that defines the first conductive traces 145.

FIG. 5 is a cross-sectional view of the structure with a second insulating layer 151 on the first insulating layer 141 as well as the first conductive traces 145 and second via openings 153 in the second insulating layer 151. The second insulating layer 151 is deposited typically by lamination or coating, and contacts and covers and extends laterally on the first insulating layer 141 and the first conductive traces 145 from above. The second insulating layer 151 typically has a thickness of 50 microns, and can be made of epoxy resin, glass-epoxy, polyimide, or the like. After the deposition of the second insulating layer 151, the second via openings 153 are formed and extend through the second insulating layer 151 to expose selected portions of the first conductive traces 145. Like the first via openings 143, the second via openings 153 can be formed by any of numerous techniques including laser drilling, plasma etching and photolithography and typically have a diameter of 50 microns.

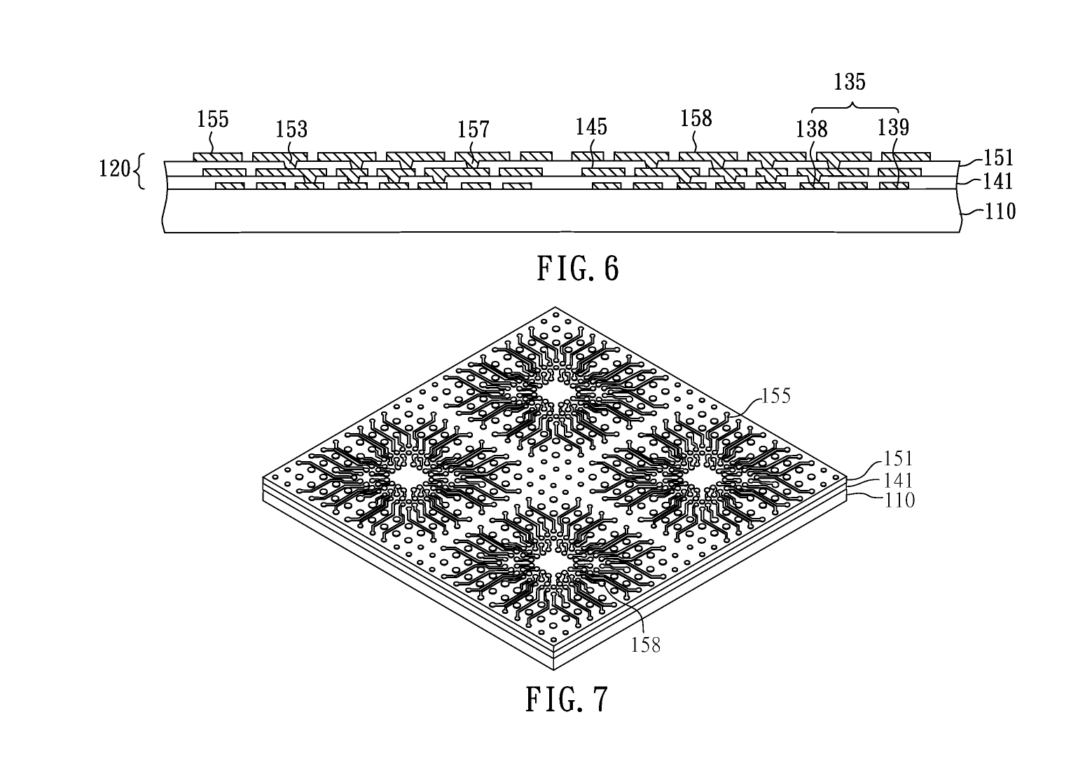

FIGS. 6 and 7 are cross-sectional and top perspective views, respectively, of the structure provided with second conductive traces 155 on the second insulating layer 151 by metal deposition and metal patterning process. The second conductive traces 155 extend from the first conductive traces 145 in the upward direction, fill up the second via openings 153 to form second conductive vias 157 in direct contact with the first conductive traces 145, and extend laterally on the second insulating layer 151. As shown in FIG. 7, the second conductive traces 155 include a patterned array of contact pads 158 that have a pitch larger than that of the bond pads 138.

At this stage, the formation of a first wiring structure 120 on the sacrificial carrier 110 is accomplished. In this illustration, the first wiring structure 120 includes routing traces 135, a first insulating layer 141, first conductive traces 145, a second insulating layer 151 and the second conductive traces 155.

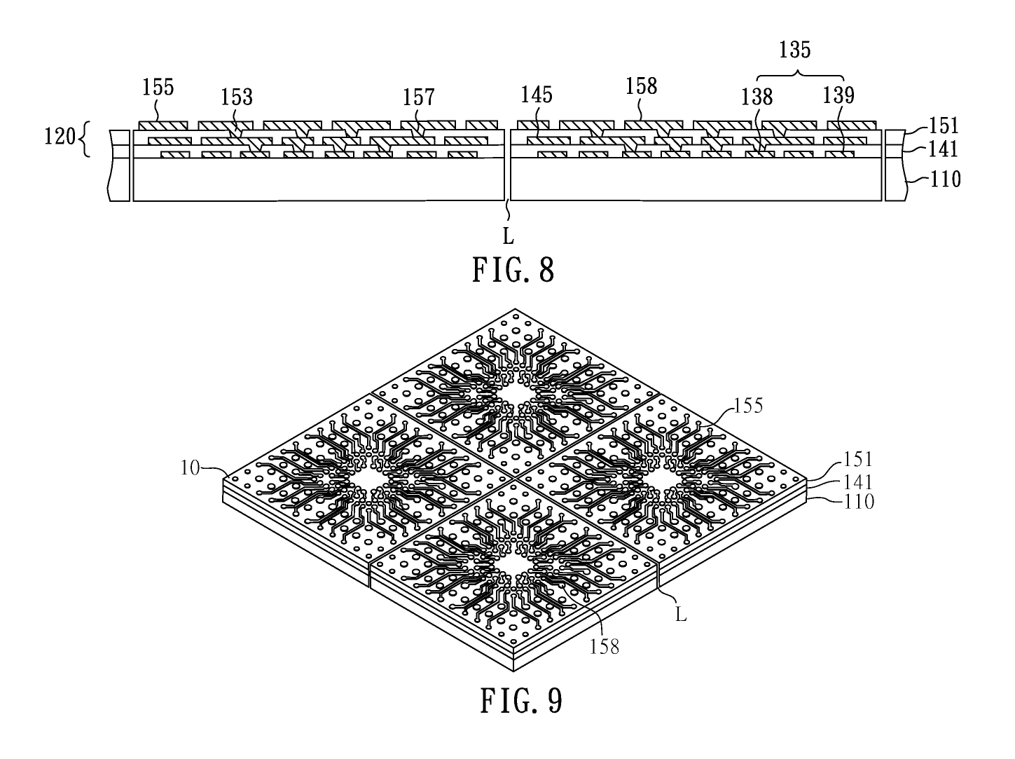

FIGS. 8 and 9 are cross-sectional and top perspective views, respectively, of the panel-scale structure of FIGS. 6 and 7 diced into individual pieces. The panel-scale structure, having the first wiring structure 120 on the sacrificial carrier 110, is singulated into individual subcomponent 10 along dicing lines “L”.

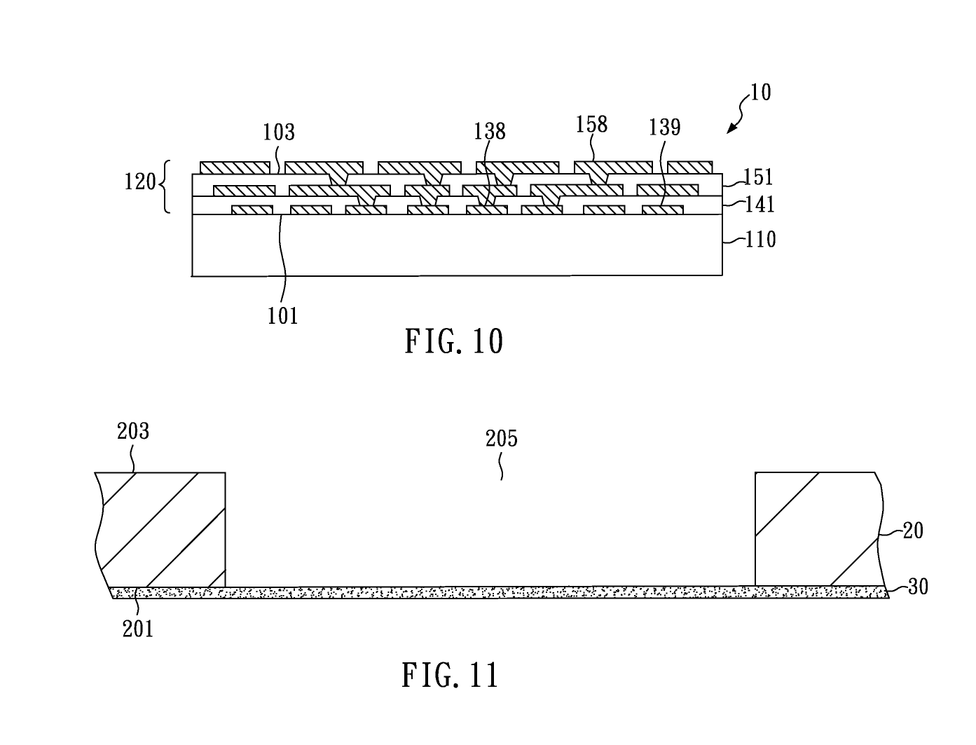

FIG. 10 is a cross-sectional view of an individual subcomponent 10 that includes a sacrificial carrier 110 and a first wiring structure 120. In this illustration, the first wiring structure 120 is a buildup routing circuitry, and has a first surface 101 adjacent to the sacrificial carrier 110, a second surface 103 opposite to the first surface 101, bond pads 138 and stacking pads 139 at the first surface 101, and contact pads 158 at the second surface 103. The bond pads 138 is to match chip I/O pads whereas the contact pads 158 on the outmost conductive traces away from the sacrificial carrier 110 have a pitch larger than that of the bond pads 138. Accordingly, the first wiring structure 120 has a pattern of traces that fan out from a finer pitch at bonds pads 138 to a coarser pitch at contact pads 158, and thus can provide first level fan-out routing/interconnection for a semiconductor device to be assembled thereon. Optionally, the stacking pads 139 on the first wiring structure 120 is to provide electrical contacts for another semiconductor device such as a plastic package or another semiconductor assembly.

FIG. 11 is a cross-sectional view of a stiffener 20 on a carrier film 30. The stiffener 20 has a first surface 201, an opposite second surface 203, and a through opening 205 that extends through the stiffener 20 between the first surface 201 and the second surface 203. The stiffener 20 can be made of ceramic, metal, resin, composites of metal, or a single or multi-layer circuitry structure which has enough mechanical robustness, and preferably has a thickness substantially the same as that of the subcomponent 10. The through openings 205 can be formed by laser cutting, punching or mechanical drilling, and preferably has a dimension that is substantially the same or slightly larger than the subsequently disposed subcomponent 10. The carrier film 30 typically is a tape, and the first surface 201 of the stiffener 20 is attached to the carrier film 30 by the adhesive property of the carrier film 30.

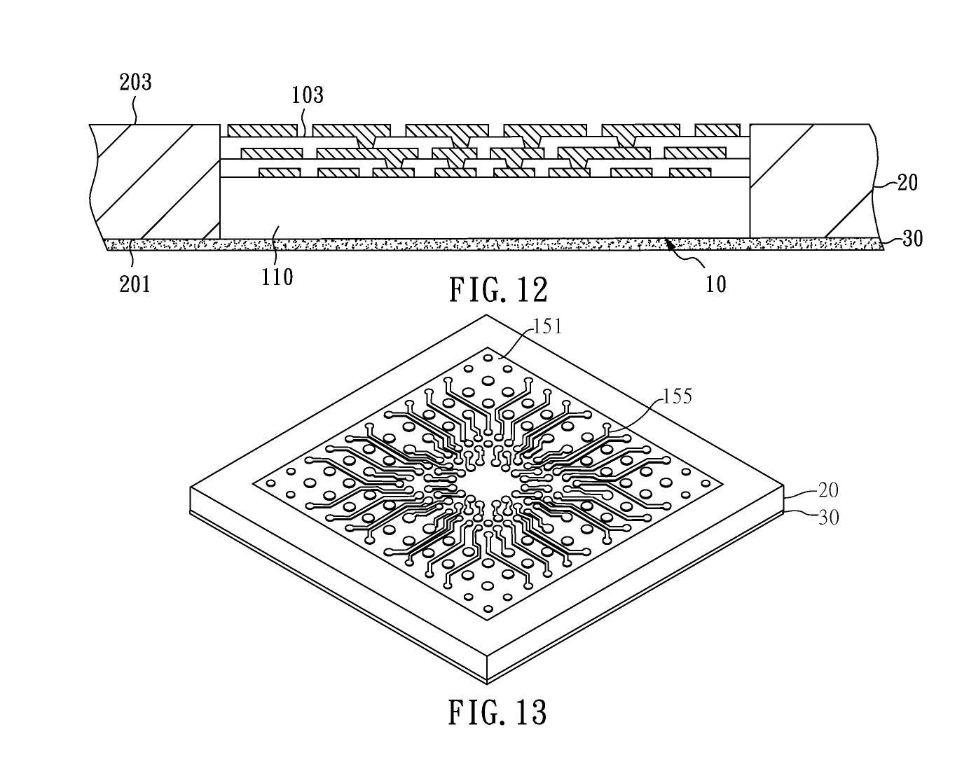

FIGS. 12 and 13 are cross-sectional and top perspective views, respectively, of the structure with the subcomponent 10 inserted in the through opening 205 of the stiffener 20 with the sacrificial carrier 110 attached on the carrier film 30. The carrier film 30 can provide temporary retention force for the subcomponent 10 steadily resided within the through opening 205. In this illustration, the subcomponent 10 is attached to the carrier film 30 by the adhesive property of the carrier film 30. Alternatively, the subcomponent 10 may be attached to the carrier film 30 by dispensing extra adhesive. After the insertion of the subcomponent 10 into the through opening 205, the outmost surface of the first wiring structure 120 is substantially coplanar with the second surface 203 of the stiffener 20 in the upward direction. In the case of the through opening 205 having a slightly larger area than the subcomponent 10, an adhesive (not shown in the figure) may be optionally dispensed in a gap (not shown in the figure) located in the through opening 205 between the subcomponent 10 and the stiffener 20 to provide secure robust mechanical bonds between the first wiring structure 120 and the stiffener 20.

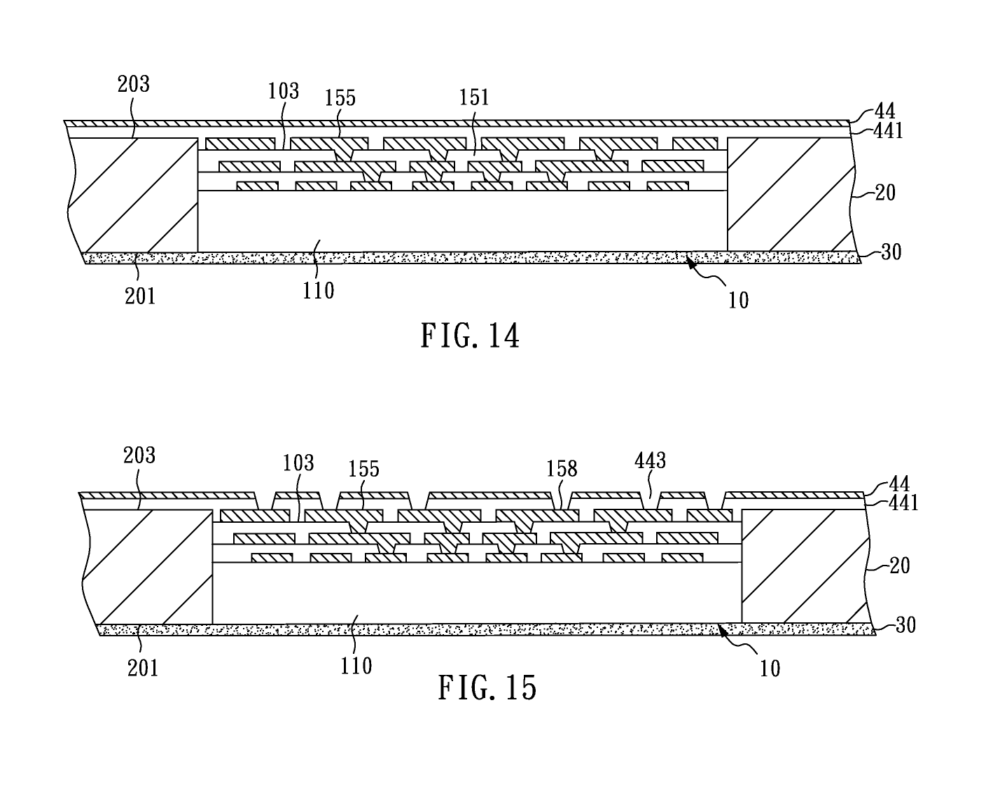

FIG. 14 is a cross-sectional view of the structure with a third insulating layer 441 and a metal layer 44 laminated/coated on the subcomponent 10 and the stiffener 20 from above. The third insulating layer 441 contacts and is sandwiched between the second insulating layer 151/the second conductive traces 155 and the metal layer 44 and between the stiffener 20 and the metal layer 44. The third insulating layer 441 can be formed of epoxy resin, glass-epoxy, polyimide and the like, and typically has a thickness of 50 microns. The metal layer 44 typically is a copper layer with a thickness of 25 microns.

FIG. 15 is a cross-sectional view of the structure provided with the third via openings 443 to expose the contact pads 158 of the second conductive traces 155. The third via openings 443 extend through the metal layer 44 and the third insulating layer 441, and are aligned with the contact pads 158 of the second conductive traces 155. Like the first and second via openings 143, 153, the third via openings 443 can be formed by any of numerous techniques including laser drilling, plasma etching and photolithography and typically have a diameter of 50 microns.

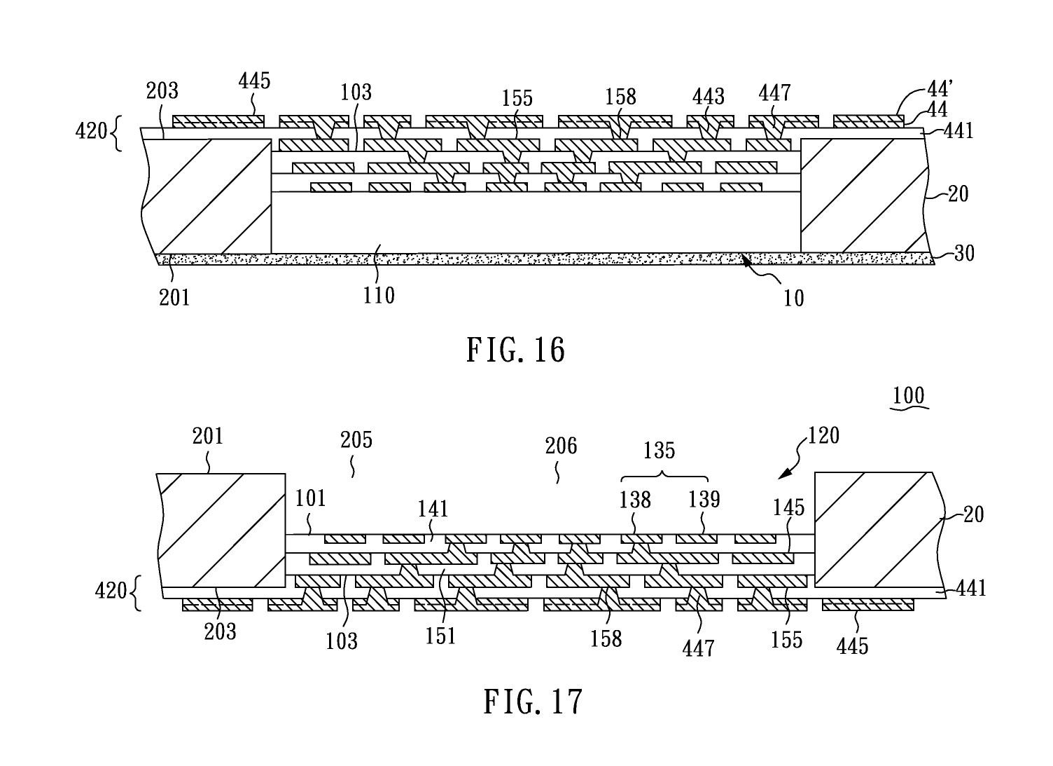

Referring now to FIG. 16, third conductive traces 445 are formed on the third insulating layer 441 by depositing a plated layer 44′ on the metal layer 44 and into the third via openings 443 and then patterning the metal layer 44 as well as the plated layers 44′ thereon. The third conductive traces 445 extend from the contact pads 158 in the upward direction, fill up the third via openings 443 to form third conductive vias 447 in direct contact with the contact pads 158, and extend laterally on the third insulating layer 441.

The metal layer 44 and the plated layer 44′ are shown as a single layer for convenience of illustration. The boundary (shown in broken lines) between the metal layers may be difficult or impossible to detect since copper is plated on copper.

At this stage, the formation of a second wiring structure 420 on the second surface 103/the second conductive traces 155 of the subcomponent 10 and the second surface 203 of the stiffener 20 is accomplished. In this illustration, the second wiring structure 420 includes a third insulating layer 441 and third conductive traces 445. The second wiring structure 420 laterally extends beyond peripheral edges of the first wiring structure 120 and substantially has a combined surface area of the first wiring structure 120 and the stiffener 20.

FIG. 17 is a cross-sectional view of the structure after removal of the carrier film 30 and the sacrificial carrier 110. The carrier film 30 is detached from the sacrificial carrier 110 and the stiffener 20, followed by removing the sacrificial carrier 110 to expose the first surface 101 of the first wiring structure 120 from above. The sacrificial carrier 110 can be removed by numerous techniques including wet chemical etching using acidic solution (e.g., ferric chloride, copper sulfate solutions), or alkaline solution (e.g., ammonia solution), electro-chemical etching, or mechanical process such as a drill or end mill followed by chemical etching. In this embodiment, the sacrificial carrier 110 made of an iron-based material is removed by a chemical etching solution that is selective between copper and iron so as to prevent the copper routing traces 135 from being etched during removal of the sacrificial carrier 110.

Accordingly, as shown in FIG. 17, a wiring board 100 is accomplished and includes a stiffener 20, a first wiring structure 120 and a second wiring structure 420, and both first and second wiring structures 120, 420 are buildup routing circuitries without a core layer.

The first wiring structure 120 is positioned within the through opening 205 of the stiffener 20, and the second wiring structure 420 is positioned beyond the through opening 205 of the stiffener 20 and laterally extends to peripheral edges of the wiring board 100. As such, the first wiring structure 120 has a smaller exposed surface area (namely, the area of the first surface 101) than that of the second wiring structure 420 (namely, the area of the lower surface of the third insulating layer 441). The first wiring structure 120 is a multi-layered routing circuitry and contains a pattern of traces that fan out from a finer pitch at the first surface 101 to a coarser pitch at the second surface 103.

The second wiring structure 420 laterally extends on the second surface 103/the second conductive traces 155 of the first wiring structure 120 and the second surface 203 of the stiffener 20, and is electrically coupled to the contact pads 158 of the first wiring structure 120 through the third conductive vias 447 of the second wiring structure 420, and includes third conductive traces 445 extending into an area outside of the through opening 205 of the stiffener 20 and laterally extending over the second surface 203 of the stiffener 20. As such, the second wiring structure 420 not only provides further fan-out wiring structure for the first wiring structure 120, but also mechanically binds the first wiring structure 120 with the stiffener 20.

The stiffener 20 surrounds peripheral edges of the first wiring structure 120 and laterally extends to the peripheral edges of the wiring board 100, can provide mechanical support and suppress warping and bending of the wiring board 100. The stiffener 20 also extends beyond the first surface 101 of the first wiring structure 120 in the upward direction to form a cavity 206 in the through opening 205 of the stiffener 20, and the second surface 203 of the stiffener 20 is substantially coplanar with the surface of the second conductive traces 155 of the first wiring structure 120 in the downward direction.

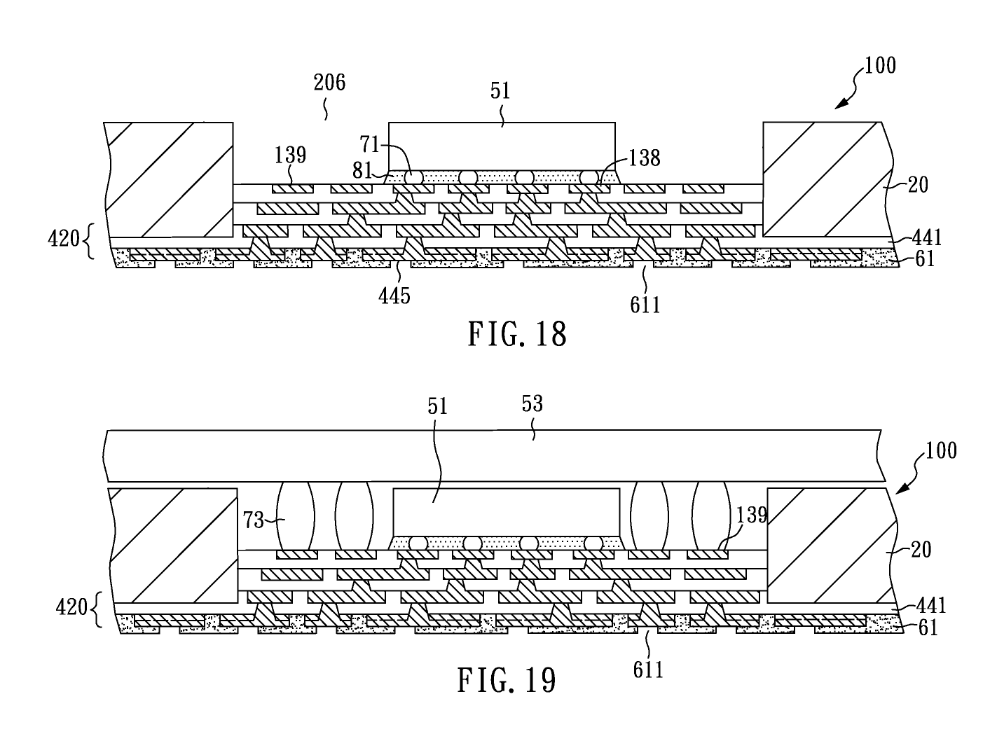

FIG. 18 is a cross-sectional view of a semiconductor assembly with a first semiconductor device 51, illustrated as a chip, mounted on the wiring board 100 illustrated in FIG. 17. In this illustration, the wiring board 100 is further provided with a solder mask layer 61 on its bottom surface. The solder mask layer 61 includes solder mask openings 611 to expose selected portions of the third conductive traces 445. The first semiconductor device 51 is positioned within the cavity 206 and is flip-chip mounted on the exposed bond pads 138 of the first wiring structure 120 via solder bumps 71. Optionally, underfill 81 can be further provided to fill the gap between the first semiconductor device 51 and the first wiring structure 120.

FIG. 19 is a cross-sectional view of a package-on-package assembly with a second semiconductor device 53 further electrically coupled to the stacking pads 139 of the first wiring structure 120 via solder balls 73. Accordingly, the second semiconductor device 53 can be electrically connected to the first semiconductor device 51 through the solder bumps 71, the solder balls 73 and the first wiring structure 110 of the wiring board 100.

### Embodiment 2

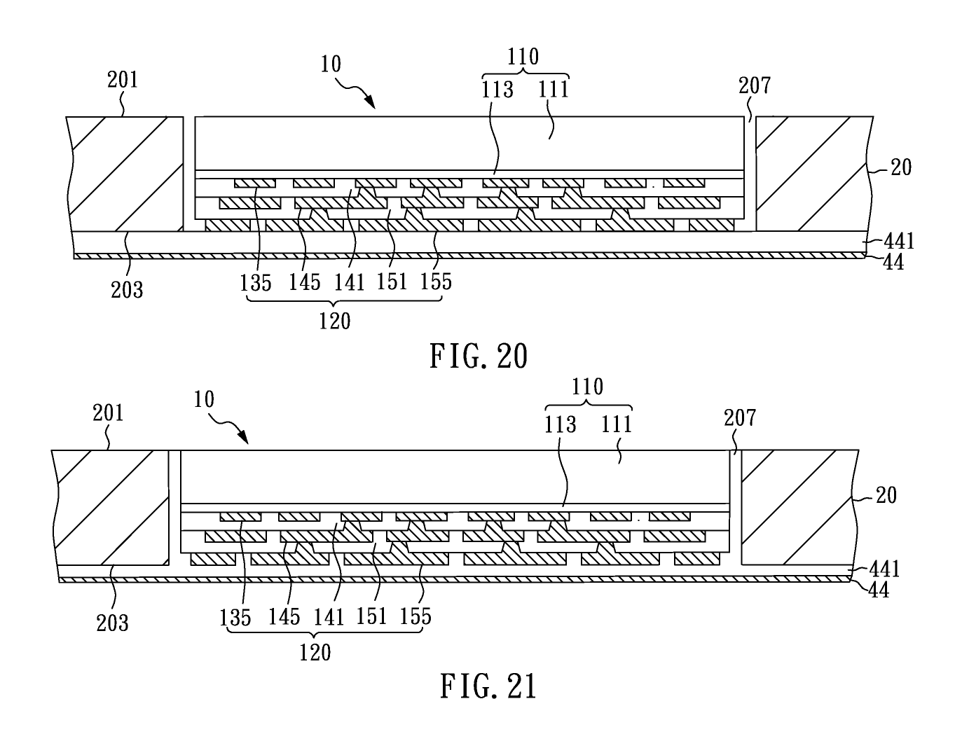

FIGS. 20-28 are schematic views showing a method of making another wiring board with an anti-warping controller in accordance with another embodiment of the present invention.

For purposes of brevity, any description in Embodiment 1 above is incorporated herein insofar as the same is applicable, and the same description need not be repeated.

FIG. 20 is a cross-sectional view of the structure with a subcomponent 10 and a stiffener 20 on a third insulating layer 441/a metal layer 44. The subcomponent 10 is similar to that illustrated in FIG. 10, except that the sacrificial carrier 110 is a double-layer structure in this embodiment. In this illustration, the third insulating layer 441 is sandwiched between the subcomponent 10 and the metal layer 44 and between the stiffener 20 and the metal layer 44, and contacts the second conductive traces 155 of the subcomponent 10 and the second surface 203 of the stiffener 20. The surface of second conductive traces 155 is substantially coplanar with the second surface 203 of the stiffener 20 in the downward direction, and a gap 207 is located in the through opening 205 between the subcomponent 10 and the stiffener 20. The gap 207 is laterally surrounded by the stiffener 20, and laterally surrounds the sacrificial carrier 110 and the first wiring structure 120. The sacrificial carrier 110 includes a support sheet 111 and a barrier layer 113 deposited on the support sheet 111, and the first wiring structure 120 is formed on the barrier layer 113. The barrier layer 113 can have a thickness of 0.001 to 0.1 mm, and may be a metal layer that is inactive against chemical etching during chemically removing the support sheet 111 and can be removed without affecting the routing traces 135. For instance, the barrier layer 113 may be made of tin or nickel when the support sheet 111 and the routing traces 135 are made of copper. Further, in addition to metal materials, the barrier layer 113 can also be a dielectric layer such as a peelable laminate film. In this embodiment, the support sheet 111 is a copper sheet, and the barrier layer 113 is a nickel layer of 3 microns in thickness.

FIG. 21 is a cross-sectional view of the structure with the third insulating layer 441 forced into the gap 207. The third insulating layer 441 is flowed into the gap 207 by applying heat and pressure. Under the heat and pressure, the third insulating layer 441 becomes compliant enough to conform to virtually any shape. As a result, the third insulating layer 441 sandwiched between the subcomponent 10 and the metal layer 44 and between the stiffener 20 and the metal layer 44 is compressed, forced out of its original shape and flows into and upward in the gap 207 to conformally coat the sidewalls of the through opening 205 and peripheral edges of the sacrificial carrier 110 and the first wiring structure 120. The third insulating layer 441 as solidified provides secure robust mechanical bonds between the subcomponent 10 and the stiffener 20, between the subcomponent 10 and the metal layer 44 and between the stiffener 20 and the metal layer 44, and thus retains the subcomponent 10 within the through opening 205 of the stiffener 20.

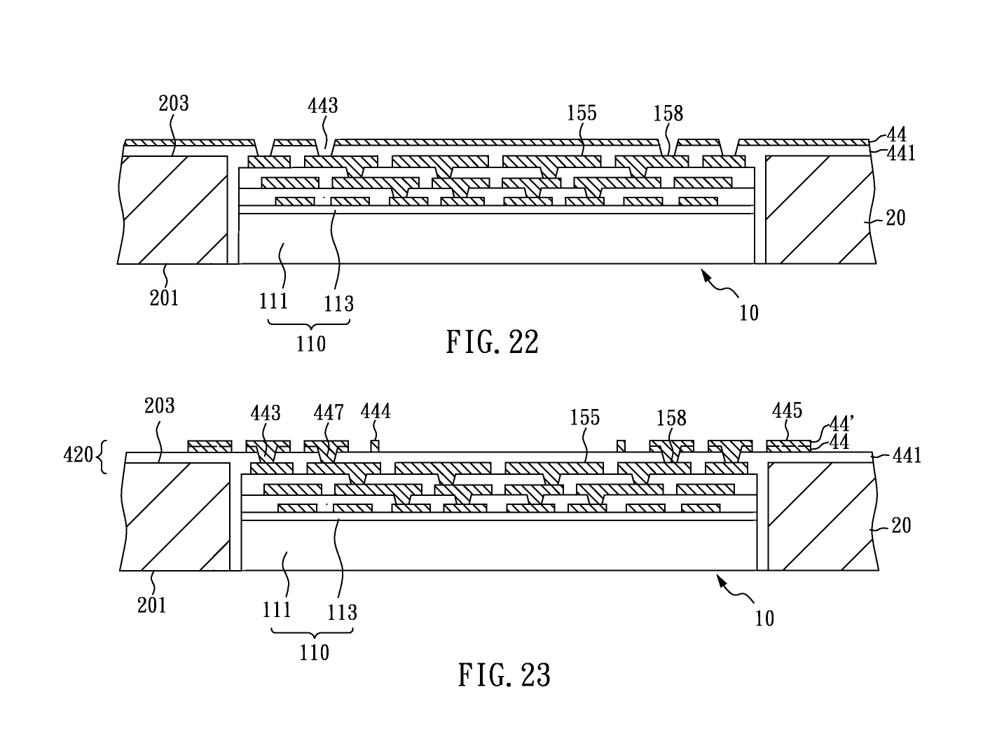

FIG. 22 is a cross-sectional view of the structure provided with the third via openings 443 to expose the contact pads 158 of the second conductive traces 155. The third via openings 443 extend through the metal layer 44 and the third insulating layer 441, and are aligned with the contact pads 158 of the second conductive traces 155.

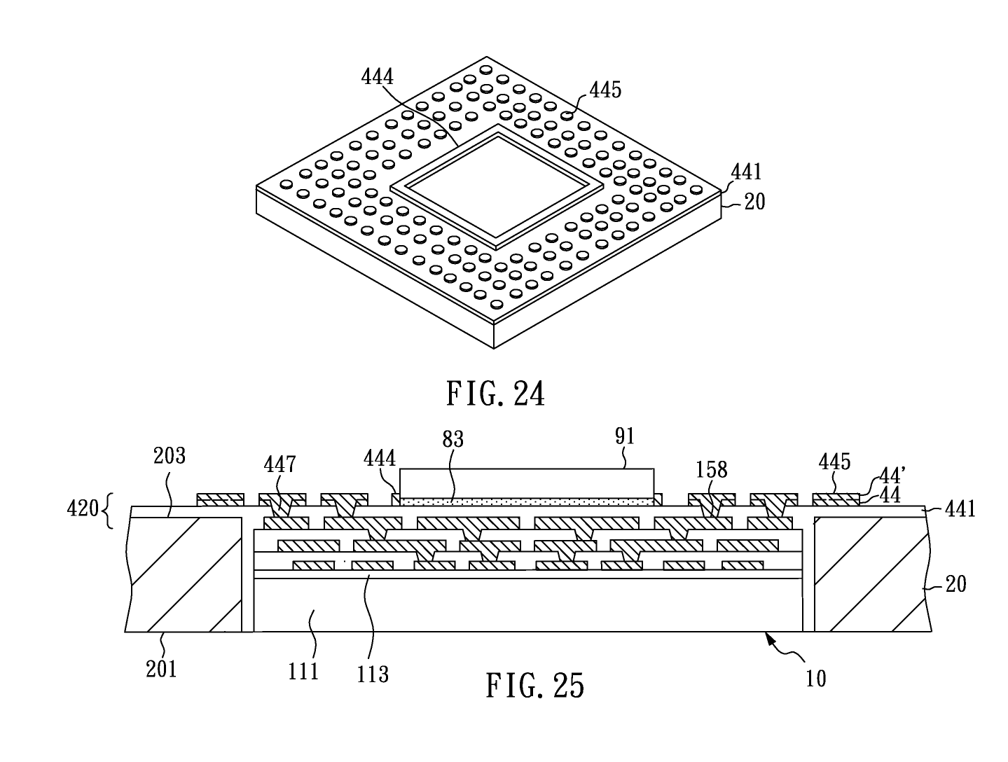

FIGS. 23 and 24 are cross-sectional and top perspective views, respectively, of the structure provided with a registration mark 444 and third conductive traces 445 on the third insulating layer 441. The registration mark 444 and third conductive traces 445 are formed by depositing a plated layer 44′ on the metal layer 44 and into the third via openings 443 and then patterning the metal layer 44 as well as the plated layers 44′ thereon. The registration mark 444 extends from the third insulating layer 441 in the upward direction and surrounds a central area of the third insulating layer 441. The third conductive traces 445 extend from the contact pads 158 in the upward direction, fill up the third via openings 443 to form third conductive vias 447 in direct contact with the contact pads 158, and extend laterally on the third insulating layer 441 beyond the central area surrounded by the registration mark 444. As shown in FIG. 24, the registration mark 444 consists of a continuous metal strip arranged in a rectangular frame configuration conforming to four lateral sides of a subsequently disposed anti-warping controller.

At this stage, the formation of a second wiring structure 420 on the first wiring structure 120 and the stiffener 20 is accomplished. In this illustration, the second wiring structure 420 includes a third insulating layer 441 and third conductive traces 445.

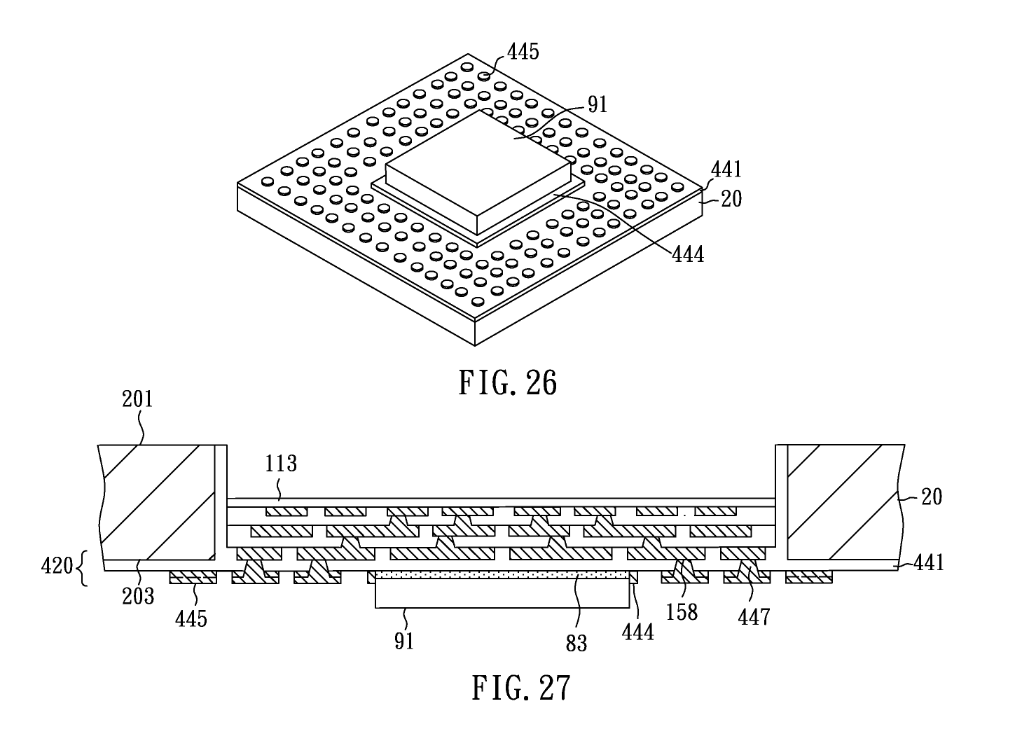

FIGS. 25 and 26 are cross-sectional and top perspective views, respectively, of the structure with an anti-warping controller 91 attached to the second wiring structure 420 using an adhesive 83. The anti-warping controller 91 is attached to the third insulating layer 441 and covers the central area in the upward direction. The registration mark 444 extends beyond the attached surface of the anti-warping controller 91 in the upward direction and is located beyond and laterally aligned with the four lateral surfaces of the anti-warping controller 91 in the lateral directions. As a result, the anti-warping controller 91 can be confined at the central area by the registration mark 444 laterally aligned with and in close proximity to peripheral edges of the anti-warping controller 91. The anti-warping controller 91 can also be attached without the registration mark 444. The anti-warping controller 91 preferably has a thickness in a range of 0.1 mm to 1.0 mm, and is typically made of high elastic modulus material (5 GPa to 500 GPa), such as ceramic, graphite, glass, metals or alloys. A resin/ceramic composite material such as molding compound also may be used for the anti-warping controller 91. Preferably, the anti-warping controller 91 has low coefficient of thermal expansion (comparable to Si around 3 ppm/K).

FIG. 27 is a cross-sectional view of the structure after removal of the support sheet 111. The support sheet 111 made of copper is removed by an alkaline etch ng solution.

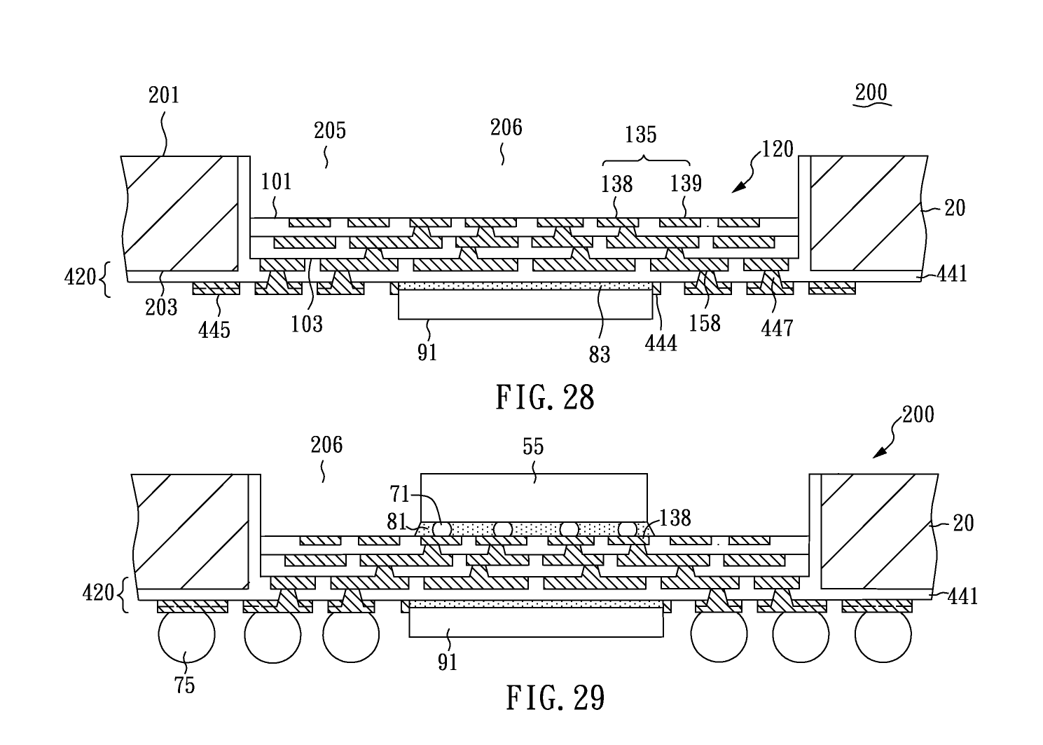

FIG. 28 is a cross-sectional view of the structure after removal of the barrier layer 113. The barrier layer 113 made of nickel is removed by an acidic etching solution to expose the first surface 101 of the first wiring structure 120 from above. In another aspect of the barrier layer 113 being a peelable laminate film, the barrier layer 113 can be removed by mechanical peeling or plasma ashing.

Accordingly, as shown in FIG. 28, a wiring board 200 is accomplished and includes a stiffener 20, a first wiring structure 120, a second wiring structure 420, a registration mark 444 and an anti-warping controller 91, and both first and second wiring structures 120, 420 are buildup routing circuitries without a core layer.

The first wiring structure 120 is positioned within the through opening 205 of the stiffener 20, and the second wiring structure 420 is positioned beyond the through opening 205 of the stiffener 20 and extends to peripheral edges of the wiring board 200. In this illustration, the first wiring structure 120 has bond pads 138 and stacking pads 139 at its first surface 101 and contact pads 158 at its second surface 103. As the size and pad spacing of the contact pads 158 are designed to be larger than those of the bond pads that match I/O pads of a chip to be assembled thereon, the first wiring structure 120 can provide a primary fan-out routing to ensure a higher manufacturing yield for the next level buildup circuitry interconnection. The second wiring structure 420 contacts and laterally extends on the first wiring structure 120 and the stiffener 20, and is electrically coupled to the contact pads 158 of the first wiring structure 120. The stiffener 20 extends beyond the first surface 101 of the first wiring structure 120 in the upward direction to form a cavity 206 in the through opening 205 of the stiffener 20.

The anti-warping controller 91 confined by the registration mark 444 is centrally aligned with the cavity 206 and covers the second wiring structure 420 in the downward direction. As a result, the stiffener 20 positioned around peripheral edges of the first wiring structure 120 can provide mechanical support for the peripheral area of the wiring board 200, whereas the anti-warping controller 91 provides mechanical support for the central area of the wiring board 200. The dual support from the stiffener 20 and the anti-warping controller 91 at two opposite sides of the wiring board 200 can effectively prevent the wiring board 200 from warping.

FIG. 29 is a cross-sectional view of a semiconductor assembly with a semiconductor device 55, illustrated as a chip, mounted on the wiring board 200 illustrated in FIG. 28. The semiconductor device 55 is positioned within the cavity 206 of the wiring board 200, and is flip-chip mounted on the exposed bond pads 138 of the first wiring structure 120 via solder bumps 71. Optionally, underfill 81 can be further provided to fill the gap between the semiconductor device 55 and the first wiring structure 120. In this illustration, the anti-warping controller 91 overlaps the chip attachment area and is thinner than solder balls 75 attached on the second wiring structure 420. As a result, the anti-warping controller 91 does not interfere with next level assembly.

### Embodiment 3

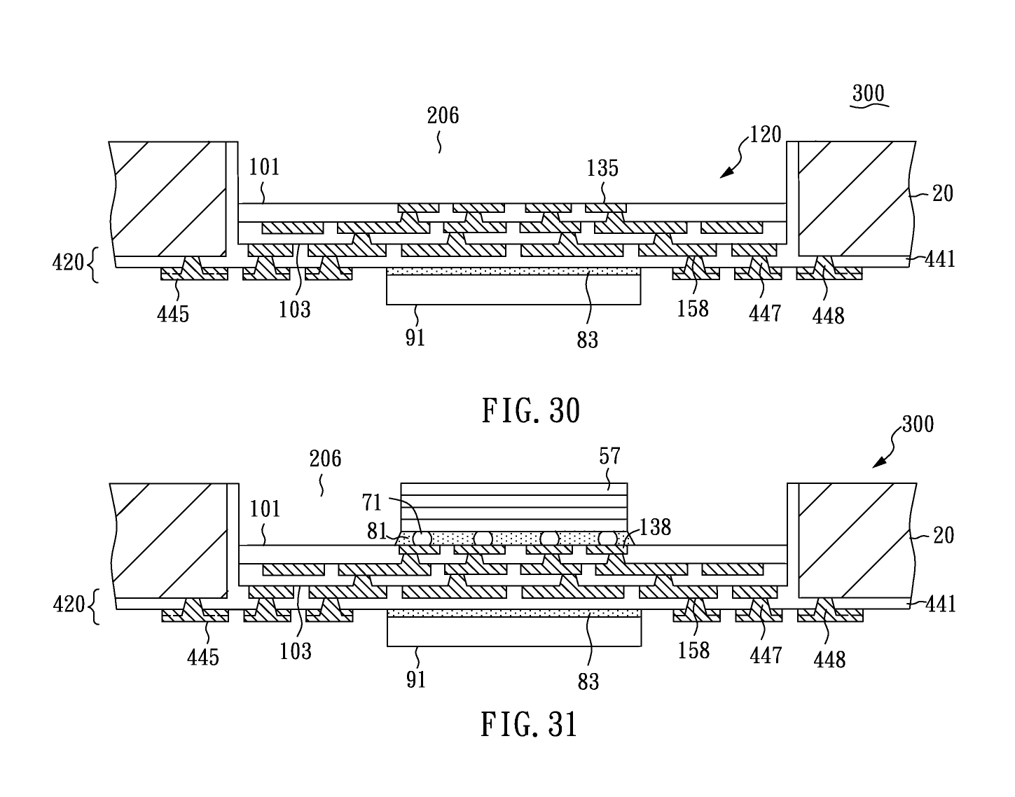

FIG. 30 is a cross-sectional view of yet another wiring board 300 with the second wiring structure 420 further electrically coupled to the stiffener 20 for ground connection in accordance with yet another embodiment of the present invention.

In this embodiment, the wiring board 300 is manufactured in a manner similar to that illustrated in Embodiment 2, except that the first wiring structure 120 includes no stacking pads at its first surface 101, no registration mark is formed on the second wiring structure 420, and the third conductive traces 445 of the second wiring structure 420 are further electrically coupled to the metallic stiffener 20 through additional third conductive vias 448 in direct contact with the stiffener 20.

FIG. 31 is a cross-sectional view of a semiconductor assembly with a semiconductor device 57, illustrated as a 3D-stacked chip, mounted on the wiring board 300 illustrated in FIG. 30. The semiconductor device 57 is positioned within the cavity 206 of the wiring board 300, and is flip-chip mounted on the exposed bond pads 138 of the first wiring structure 120 via solder bumps 71. Optionally, underfill 81 can be further provided to fill the gap between the semiconductor device 57 and the first wiring structure 120.

The wiring board and assemblies described above are merely exemplary. Numerous other embodiments are contemplated. In addition, the embodiments described above can be mixed-and-matched with one another and with other embodiments depending on design and reliability considerations. For instance, the stiffener may include multiple through openings arranged in an array and each through opening accommodates a first wiring structure therein. Also, the second wiring structure can include additional conductive traces to receive and route additional contact pads of additional first wiring structures, and additional anti-warping controllers may be further provided and aligned with additional through openings of the stiffener.

As illustrated in the aforementioned embodiments, a distinctive wiring board is configured to exhibit improved reliability, which includes a stiffener, a first wiring structure, a second wiring structure, an optional anti-warping controller, and an optional registration mark.

The stiffener has a through opening between opposite first and second surfaces thereof, and may be a single or multi-layer structure optionally with embedded single-level conductive traces or multi-level conductive traces. In a preferred embodiment, the stiffener surrounds peripheral edges of the first wiring structure and laterally extends to the peripheral edges of the wiring board. The stiffener can be made of any material which has enough mechanical robustness, such as metal, composites of metal, ceramic, resin or other non-metallic materials. Accordingly, the stiffener located around peripheral edges of the first wiring structure can provide mechanical support for the peripheral area of the wiring board to suppress warping and bending of the wiring board.

The first and second wiring structures can be buildup routing circuitries without a core layer and positioned within and beyond the through opening of the stiffener, respectively. The second wiring structure laterally extends beyond the peripheral edges of the first wiring structure, and can have a larger exposed surface area than that of the first wiring structure. Preferably, the second wiring structure extends to peripheral edges of the wiring board and substantially has a combined surface area of the first wiring structure and the stiffener. The first and second wiring structures each can include at least one insulating layer and conductive traces that fill up via openings in the insulating layer and extend laterally on the insulating layer. The insulating layer and the conductive traces are serially formed in an alternate fashion and can be in repetition when needed.

The first wiring structure can be formed on a detachable sacrificial carrier to form a subcomponent, followed by inserting the subcomponent into the through opening of the stiffener, preferably with peripheral edges of the first wiring structure and the sacrificial carrier in close proximity to sidewalls of the through opening of the stiffener. Specifically, the first wiring structure can be formed to include routing traces on the sacrificial carrier, an insulating layer on the routing traces and the sacrificial carrier, and conductive traces that extend from selected portions of the routing traces and fill up via openings in the insulating layer to form conductive vias and laterally extend on the insulating layer. Further, the first wiring structure may include additional insulating layers, additional via openings, and additional conductive traces if needed for further signal routing. Also, the first wiring structure may optionally include one or more passive components embedded therein. In the present invention, the step of forming the first wiring structure on the sacrificial carrier can be executed by directly forming the first wiring structure on the sacrificial carrier, or by separately forming and then detachably adhering the first wiring structure to the sacrificial carrier. For the first wiring structure, the routing traces can includes bond pads that match chip I/O pads, whereas the outmost conductive traces away from the sacrificial carrier can include contact pads with a pitch larger than that of the bond pads. Optionally, the routing traces may further include stacking pads to provide electrical contacts for another semiconductor device such as a plastic package or another semiconductor assembly. As a result, the first wiring structure can be a multi-layered routing circuitry, and have bond pads and optional stacking pads at its first surface and contact pads at its second surface that can be electrically coupled to the bond pads and optionally to the stacking pads by conductive vias. Accordingly, in a preferred embodiment, the first wiring structure has a pattern of traces that fan out from a finer pitch at the bonds pads to a coarser pitch at the contact pads, and provides first level fan-out routing/interconnection for a semiconductor device to be assembled thereon. The first surface of the first wiring structure faces in the same direction as the first surface of the stiffener, whereas the second surface of the first wiring structure faces in the same direction as the second surface of the stiffener. For the convenience of below description, the direction in which the first surfaces of the first wiring structure and the stiffener face is defined as the first vertical direction, and the direction in which the second surfaces of the first wiring structure and the stiffener face is defined as the second vertical direction. The surfaces, facing in the first vertical direction, of the bond pads, the optional stacking pads and the innermost insulating layer adjacent to the sacrificial carrier can be substantially coplanar with each other, whereas the surface, facing in the second vertical direction, of the outmost conductive traces away from the sacrificial carrier preferably is substantially coplanar with the second surface of the stiffener. Further, the stiffener can extend beyond the first surface of the first wiring structure in the first vertical direction so as to form a cavity in the through opening of the stiffener after removing the sacrificial carrier to expose the first surface of the first wiring structure. Accordingly, a semiconductor device can be positioned within the cavity and electrically coupled to the bond pads exposed from the cavity. Optionally, an adhesive may be dispensed in a gap located in the through opening between the subcomponent and the stiffener after the subcomponent is inserted into the through opening of the stiffener, thereby providing secure robust mechanical bonds between the first wiring structure and the stiffener. Alternatively, the gap between the subcomponent and the stiffener may be filled with an insulating layer of the second wiring structure. Accordingly, the sidewalls of the through opening and the peripheral edges of the first wiring structure and the sacrificial carrier can be coated with the adhesive or the insulating layer.

The second wiring structure can be formed on the second surfaces of the first wiring structure and the stiffener to provide further fan-out routing/interconnection for the first wiring structure after the insertion of the first wiring structure into the through opening of the stiffener. As the second wiring structure can be electrically coupled to the first wiring structure through conductive vias of the second wiring structure, the electrical connection between the first wiring structure and the second wiring structure can be devoid of soldering material. Also, the interface between the stiffener and the second wiring structure can be devoid of solder or adhesive. More specifically, the second structure can be formed to include an insulating layer on the second surfaces of the first wiring structure and the stiffener, and conductive traces that extend from the contact pads of the first wiring structure and optionally from the second surface of the stiffener and fill up via openings in the insulating layer of the second wiring structure and laterally extend on the insulating layer of the second wiring structure. As a result, the second wiring structure can contact and be electrically coupled to the contact pads of the first wiring structure for signal routing, and optionally further electrically coupled to the second surface of the stiffener for ground connection. Further, the second wiring structure may include additional insulating layers, additional via openings, and additional conductive traces if needed for further signal routing. The outmost conductive traces of the second wiring structure can accommodate conductive joints, such as solder balls, for electrical communication and mechanical attachment with for the next level assembly or another electronic device.

Before the formation of the second wiring structure, a carrier film (typically an adhesive tape) may be used to provide temporary retention force. For instance, the carrier film can temporally adhere to the sacrificial carrier and the first surface of the stiffener to retain the subcomponent within the through opening of the stiffener, optionally followed by dispensing an adhesive in a gap between the stiffener and the first wiring structure and between the stiffener and the sacrificial carrier, as mentioned above. After the second wiring structure is formed on the first wiring structure and the stiffener, the carrier film can be detached therefrom. As an alternative, the subcomponent and the stiffener may be directly positioned on an insulating layer, with the outmost conductive traces of the first wiring structure and the second surface of the stiffener in contact with the insulating layer, followed by bonding the insulating layer to the first wiring structure and the stiffener, preferably with the insulating layer flowed into the gap between the first wiring structure and the stiffener and between the sacrificial carrier and the stiffener. As a result, the insulating layer can provide secure robust mechanical bonds between the subcomponent and the stiffener and retain the subcomponent within the through opening of the stiffener. Subsequently, the second wiring structure, including the insulating layer bonded to the first wiring structure and the stiffener, can be formed to electrically couple the first wiring structure.

The sacrificial carrier, which provides rigidity support for the first wiring structure, can be detached from the first wiring structure by a chemical etching process or a mechanical peeling process after the formation of the second wiring structure. The sacrificial carrier can have a thickness of 0.1 mm to 2.0 mm and may be made of any conductive or non-conductive material, such as copper, nickel, chromium, tin, iron, stainless steel, silicon, glass, graphite, plastic film, or other metal or non-metallic materials. For the aspect of detaching the sacrificial carrier by a chemical etching process, the sacrificial carrier typically is made of chemically removable materials. In consideration of the bond pads in contact with the sacrificial carrier not being etched during removal of the sacrificial carrier, the sacrificial carrier may be made of nickel, chromium, tin, iron, stainless steel, or any other material that can be removed using an etching solution inactive to the bond pads as well as the optional stacking pads made of copper. Alternatively, the bond pads as well as the optional stacking pads are made of any stable material against etching during removal of the sacrificial carrier. For instance, the bond pads as well as the optional stacking pads may be gold pads in the case of the sacrificial carrier being made of copper. Additionally, the sacrificial carrier also can be a multi-layer structure having a barrier layer and a support sheet, and the first wiring structure is formed on the barrier layer of the sacrificial carrier. As the first wiring structure is spaced from the support sheet by a barrier layer disposed therebetween, the support sheet can be removed without damage on the routing traces of the first wiring structure even the routing traces and the support sheet are made of the same material. The barrier layer may be a metal layer that is inactive against chemical etching during chemically removing the support sheet and can be removed using an etching solution inactive to the routing traces. For instance, the support sheet made of copper or aluminum may be provided with a nickel, chromium or titanium layer as the barrier layer on its surface, and the routing traces made of copper or aluminum are deposited on the nickel, chromium or titanium layer. Accordingly, the nickel, chromium or titanium layer can protect the routing traces from etching during removal of the support sheet. As an alternative, the barrier layer may be a dielectric layer that can be removed by, for example, a mechanical peeling or plasma ashing process. For instance, a release layer may be used as a barrier layer disposed between the support sheet and the first wiring structure, and the support sheet can be removed together with the release layer by a mechanical peeling process.

The optional anti-warping controller can be aligned with the through opening of the stiffener and attached on the second wiring structure using an adhesive to provide mechanical support for the central area of the wiring board. In a preferred embodiment, the anti-warping controller covers an area that partially or entirely overlaps the attachment area of the semiconductor device assembled on the bond pads and is thinner than solder balls to be attached on the second wiring structure, so that the anti-warping controller does not interfere with next level assembly. The anti-warping controller can have a thickness in a range of 0.1 mm to 1.0 mm and may be made of high elastic modulus material (5 GPa to 500 GPa), such as ceramic, graphite, glass, metals or alloys. A resin/ceramic composite material such as molding compound also may be used for the anti-warping controller. Preferably, the anti-warping controller has low coefficient of thermal expansion (comparable to Si around 3 ppm/K), and is attached on the second wiring structure before the removal of the sacrificial carrier.

The optional registration mark can be formed to confine the anti-warping controller at the predetermined location. In a preferred embodiment, the registration mark contacts and extends from the outmost insulating layer of the second wiring structure and extends beyond the attached surface of the anti-warping controller in the second vertical direction. As such, the placement accuracy of the anti-warping controller can be provided by the registration mark that is laterally aligned with and in close proximity to and surrounds the peripheral edges of the anti-warping controller. The registration mark can be simultaneously formed while forming the outmost conductive traces of the second wiring structure, and can have various patterns against undesirable movement of the anti-warping controller. For instance, the registration mark can include a continuous or discontinuous strip or an array of posts and be laterally aligned with four lateral surfaces of the anti-warping controller to define an area with the same or similar topography as the anti-warping controller. Specifically, the registration mark can be aligned along and conform to four sides, two diagonal corners or four corners of the anti-warping controller. As a result, the registration mark located beyond the anti-warping controller can prevent the undesired lateral displacement of the anti-warping controller. Also, the attachment of the anti-warping controller can be executed without the registration mark.

The present invention also provides a semiconductor assembly in which a semiconductor device is electrically coupled to the bond pads of the aforementioned wiring board. Specifically, the semiconductor device can be positioned in the cavity of the wiring board and electrically connected to the wiring board using various using a wide variety of connection media such as bumps on the bond pads of the wiring board. The semiconductor device can be a packaged or unpackaged chip. For instance, the semiconductor device can be a bare chip, or a wafer level packaged die, etc. Alternatively, the semiconductor device can be a stacked-die chip. Additionally, a second semiconductor device may be further provided and electrically coupled to the stacking pads of the wiring board using conductive joints such as solder balls. Accordingly, the present invention can provide a package-on-package assembly that includes a first semiconductor device positioned in the cavity of the wiring board and electrically coupled to the bond pads of the wiring board, and a second semiconductor device positioned above the first semiconductor device and electrically coupled to the stacking pads of the wiring board. In a preferred embodiment, the first semiconductor device is flip mounted on the bond pads, and the second semiconductor device is positioned above the first surface of the stiffener as well as the first semiconductor device and mounted on the stacking pads. Optionally, a filler material can be further provided to fill the gap between the first semiconductor device and the first wiring structure of the wiring board.

The term “cover” refers to incomplete or complete coverage in a vertical and/or lateral direction. For instance, in the cavity-up position, the optional anti-warping controller covers the second wiring structure in the downward direction regardless of whether another element such as the adhesive is between the anti-warping controller and the second wiring structure.

The phrases “mounted on” and “attached on” include contact and non-contact with a single or multiple element(s). For instance, the optional anti-warping controller can be attached on the second wiring structure regardless of whether it contacts the second wiring structure or is separated from the second wiring structure by an adhesive.

The phrase “aligned with” refers to relative position between elements regardless of whether elements are spaced from or adjacent to one another or one element is inserted into and extends into the other element. For instance, the registration mark is laterally aligned with the anti-warping controller since an imaginary horizontal line intersects the registration mark and the anti-warping controller, regardless of whether another element is between the registration mark and the anti-warping controller and is intersected by the line, and regardless of whether another imaginary horizontal line intersects the anti-warping controller but not the registration mark or intersects the registration mark but not the anti-warping controller. Likewise, the anti-warping controller is aligned with the through opening of the stiffener.

The phrase “in close proximity to” refers to a gap between elements not being wider than the maximum acceptable limit. As known in the art, when the gap between the anti-warping controller and the registration mark is not narrow enough, the anti-warping controller may not be accurately confined at a predetermined location. The maximum acceptable limit for a gap between the anti-warping controller and the registration mark can be determined depending on how accurately it is desired to dispose the anti-warping controller at the predetermined location. Similarly, in some cases, once the location error of the subcomponent goes beyond the maximum limit, it is impossible to align the predetermined portion of the first wiring structure with a laser beam, resulting in the electrical connection failure between the first wiring structure and the second wiring structure. According to the contact pad size of the first wiring structure, those skilled in the art can ascertain the maximum acceptable limit for a gap between the first wiring structure and the stiffener through trial and error to ensure the conductive vias being of the second wiring structure aligned with the contact pads of the first wiring structure. Thereby, the description “the registration mark is in close proximity to the peripheral edges of the anti-warping controller” means that the gap between the peripheral edges of the anti-warping controller and the registration mark is narrow enough to prevent the location error of the anti-warping controller from exceeding the maximum acceptable error limit. Likewise, the description “peripheral edges of the first wiring structure and the sacrificial carrier are in close proximity to sidewalls of the through opening of the stiffener” means that the gap between the peripheral edges of the sacrificial carrier and the sidewalls of the through opening and between the peripheral edges of the first wiring structure and the sidewalls of the through opening is narrow enough to prevent the location error of the subcomponent from exceeding the maximum acceptable error limit. For instance, the gaps in between the anti-warping controller and the registration mark may be in a range of about 25 to 100 microns, and the gaps in between the peripheral edges of the subcomponent and the sidewalls of the through opening preferably may be in a range of about 10 to 50 microns.

The phrases “electrical connection”, “electrically connected” and “electrically coupled” refer to direct and indirect electrical connection. For instance, the first conductive traces directly contact and are electrically connected to the routing traces and the second conductive traces are spaced from and electrically connected to the routing traces by the first conductive traces.

The “first vertical direction” and “second vertical direction” do not depend on the orientation of the wiring board, as will be readily apparent to those skilled in the art. For instance, the first surfaces of the first wiring structure and the stiffener face the first vertical direction and the second surfaces of the first wiring structure and the stiffener face the second vertical direction regardless of whether the wiring board is inverted. Thus, the first and second vertical directions are opposite one another and orthogonal to the lateral directions. Furthermore, the first vertical direction is the upward direction and the second vertical direction is the downward direction in the cavity-up position, and the first vertical direction is the downward direction and the second vertical direction is the upward direction in the cavity-down position.

The wiring board according to the present invention has numerous advantages. For instance, the stiffener can provide an anti-warping platform for the second wiring structure formation thereon to suppress warping and bending of the wiring board. The first wiring structure within the through opening of the stiffener provides a first level fan-out routing/interconnection for a semiconductor device to be assembled thereon, whereas the second wiring structure on the first wiring structure and the stiffener provides a second level fan-out routing/interconnection. As such, a semiconductor device with fine pads can be electrically coupled to one side of the first wiring structure with pad pitch that matches the semiconductor device, and the second wiring structure is electrically coupled to the other side of the first wiring structure with larger pad pitch and further enlarges the pad size and pitch of the semiconductor device. The optional anti-warping controller can provide another anti-warping platform for the first and second wiring structures to further resolve the local warping problem at the area aligned with the through opening of the stiffener. By the mechanical robustness of the stiffener and the anti-warping controller at the two opposite sides of the wiring board, both the general rigidity and local warping problems can be resolved. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A wiring board with dual wiring structures integrated together, comprising:
a stiffener having a through opening that extends through the stiffener;
a first wiring structure having a multi-layered routing circuitry and positioned within the through opening of the stiffener; and
a second wiring structure that is electrically coupled to the first wiring structure and includes at least one conductive trace laterally extending over a surface of the stiffener.

2. The wiring board of claim 1, wherein the first wiring structure has a smaller exposed surface area than that of the second wiring structure.

3. The wiring board of claim 2, wherein the stiffener extends beyond the exposed surface of the first wiring structure to form a cavity in the through opening of the stiffener.

4. The wiring board of claim 1, wherein the second wiring structure is electrically coupled to the first wiring structure through conductive vias.

5. The wiring board of claim 1, wherein both the first and the second wiring structures are buildup routing circuitries without a core layer.

6. The wiring board of claim 1, further comprising an anti-warping controller that is attached on the second wiring structure.

7. A method of making a wiring board with dual wiring structures integrated together, comprising:
forming a first wiring structure on a detachable sacrificial carrier;
providing a stiffener that has a through opening extending through the stiffener;
inserting the first wiring structure and the sacrificial carrier into the through opening of the stiffener;
forming a second wiring structure that is electrically coupled to the first wiring structure and includes at least one conductive trace laterally extending over a surface of the stiffener; and
removing the sacrificial carrier to expose the first wiring structure.

8. The method of claim 7, wherein the step of removing the sacrificial carrier includes a chemical etching process or a mechanical peeling process.

9. The method of claim 7, further comprising a step of attaching an anti-warping controller on the second wiring structure before the step of removing the sacrificial carrier.
